(19) United States
(12) Patent Application Publication
(10) Pub. No.: US 2020/0305278 A1
(43) Pub. Date: Sep. 24, 2020

(54) PROCESS FOR MANUFACTURING A FUNCTIONAL FLEXIBLE CELLULOSIC SUBSTRATE, SETUP FOR IMPLEMENTING SAID PROCESS

(71) Applicants: INSTITUT POLYTECHNIQUE DE GRENOBLE, GRENOBLE CEDEX 1 (FR); CENTRE NATIONAL DE LA RECHERCHE SCIENTIFIQUE -CNRS-, PARIS (FR)

(72) Inventors: Denis CURTIL, COUBLEVIE (FR); Didier CHAUSSY, Brié et Angonnes (FR); Davide BENEVENTI, SAINT MARTIN D'HERES (FR); Lara GAULIER, GRENOBLE (FR)

(21) Appl. No.: 16/753,292

(22) PCT Filed: Oct. 4, 2018
(86) PCT No.: PCT/FR2018/052457

§ 371 Date: Apr. 2, 2020

(30) Foreign Application Priority Data
Oct. 4, 2017 (FR) 1759307

(51) Int. Cl. H05K 1/03; D21J 3/12; D21H 25/04; H05K 3/12; D21H 11/20; D21H 15/10

(52) U.S. Cl. CPC H05K 1/0393; H05K 1/0386; D21J 3/12; H05K 2201/0137; H05K 3/1275; D21H 11/20; D21H 15/10; D21H 25/04

(57) ABSTRACT

A process for manufacturing a flexible cellulosic substrate comprises at least one functional circuit and/or at least one functional board. The flexible cellulosic substrates are made functional by printing with a functional ink, which provides good performance (signal speed/dielectric properties of the substrate), is economical, thermally and dimensionally stable, and is able to be produced simply and reproducibly at an industrial rate. The process starts with an aqueous fibrous suspension comprising paper pulp and/or a pulp of (micro/macro) cellulose fibrils and produces a wet fibrous mat from this suspension. One of the faces of the wet fibrous mat is printed by means of at least one functional ink capable of transmitting, emitting, and/or processing at least one signal in order to produce at least one topography comprising at least one track for circulation of the signal. Printed circuits and functional boards are obtained by the manufacturing process.

### TECHNICAL FIELD

The field of the invention is the manufacture of functional boards or circuits which have a paper-based substrate and which are capable of carrying, circulating, and/or processing a signal, in particular an electrical signal in the case of printed electrical circuits or circuit boards.

In particular, the invention relates to the manufacturing on an industrial scale of printed circuits/circuit boards on flexible and cellulosic substrates.

The invention also relates to objects resulting from such manufacture, including in particular circuit boards comprising electrically conductive tracks and electronic components, printed on a paper-based substrate.

The setups and kits for carrying out such manufacturing constitute other aspects of the invention.

### State of the Art—Technical Problem

The explosion of the market for electronic devices of all kinds which comprise printed circuits and circuit boards is creating a constant need to improve the production of substrates comprising electrically conductive tracks and electronic components. These electronic substrates need to be produced at low cost and very efficiently.

Furthermore, the efficiency of these printed circuits and circuit boards must continually increase. This depends in particular on the speed at which the signals travel, in this case the electrical signals in these circuits and these boards. However, this speed is directly linked to the dielectric constant of the component material of the substrates of these circuits and boards.

Conventionally, these substrates are composed of rigid composites produced by impregnating a fibrous substrate, for example paper, with an epoxy resin or a phenolic resin.

These composites have the disadvantage of being relatively expensive in terms of production and recycling, and moreover of being thermally unstable. In addition, the dielectric constant of these composites is not optimal, particularly regarding the difficulties posed by their production.

U.S. Pat. No. 6,042,936A thus describes a substrate formed by a non-woven fibrous mat comprising wood pulp, a flocculating agent formed by a cationic polyacrylamide, and a filler of low dielectric constant composed of hollow glass microspheres. This flexible fibrous substrate is converted into a flat rigid substrate by impregnation until saturation, with a phenolic or epoxy resin which crosslinks.

In addition to these composite substrates, an entire technology of electronics printed on paper has been developed which aims to be simpler and more economical and which can be implemented on very large surface areas.

Indeed, paper and specifically cellulose is a dielectric, i.e. an insulator, that is not electrically inert and which has electrostatic dipoles on the atomic scale that interact with external electromagnetic fields. The quantity which characterizes dielectrics is the dielectric permittivity, which describes the polarization of the material.

This makes paper a prime candidate for the production of electronic substrates.

In addition, the printing of electrical circuits and electronic components on a flexible paper substrate can be carried out directly and continuously at a very high rate, as the paper leaves the papermaking machine.

In such technology, the paper may be coated or uncoated.

Uncoated paper has been found to be unsuitable for printing electrically conductive tracks, due to the fact that the roughness and porosity of uncoated paper are very high. This results in discontinuity in the electrically conductive tracks, which thus have a relatively low conductivity. Such an observation is made on page 6, paragraph 5 of patent FR3012153 B1.

That same document then explains that the coated papers have pigment layers bonded with a synthetic latex, which reduces their porosity and surface roughness. However, printing on such coated papers with electrically conductive inks is unsatisfactory because the coated papers cannot withstand the heat treatments essential to annealing the electrically conductive inks used. In addition, these coated papers have the inconvenience of turning yellow starting at 140° C.

As an alternative, FR3012153 B1 proposes a paper having a fibrous substrate comprising at least one face covered with at least one layer, said layer comprising or consisting of:
100 parts by dry weight of pigments (kaolin, CaCO₃ . . . ),
5 to 50 parts by dry weight of one or more binders resistant to exposure to temperatures within the 140° C. to 200° C. range and having a glass transition temperature below 20° C., in particular one or more acrylic binders (Acronal® LN579S which has a glass transition temperature of less than or equal to 20° C., preferably less than or equal to 10° C.,
0 to 15 parts by dry weight, for example 8 parts, of thickening agent such as polyvinyl alcohol.

Such paper intended for printed electronics remains deficient however, particularly because of its cost, its heat resistance (yellowing) which leaves room for improvement, and its insufficient dimensional stability (deformations or shrinkage during annealing at high temperature).

Indeed, the deposition of conductive inks by conventional printing techniques on such special coated papers (screen printing, preferably rotary screen printing, flexography, or inkjetting, etc.) poses the following problems:
1) these special coated papers are subject to delamination and cracking phenomena when folded, which obviously adversely affect the quality of the printing;
2) these special coated papers developed for electronic printing are inherently expensive;
3) the electrically conductive inks used for printing on these special coated papers are themselves expensive and complicate the printing, due to the fact that it requires additional steps such as annealing;
4) the lamination of sheets of these papers in order to manufacture multiple layers is done by bonding with adhesives, which is a complex and costly industrial operation.

### OBJECTIVES OF THE INVENTION

Under these circumstances, the present invention aims to satisfy at least one of the objectives set forth below.
One of the essential objectives of the present invention is to provide an improved process for manufacturing a flexible cellulosic substrate which comprises at least one functional circuit and/or is akin to at least one functional board, this circuit and/or this board being capable of carrying, circulating, and/or processing a signal.
One of the essential objectives of the present invention is to provide an improved, simple-to-implement process for manufacturing a flexible cellulosic substrate which comprises at least one printed electronic/electrical circuit and/or is akin to at least one circuit board.
One of the essential objectives of the present invention is to provide an improved and economical process for manufacturing a functional flexible cellulosic substrate (printed electronic).
One of the essential objectives of the present invention is to provide an improved process for manufacturing a functional flexible cellulosic substrate (printed electronic) which does not delaminate/has little or no cracking.
One of the essential objectives of the present invention is to provide an improved process for manufacturing a functional flexible cellulosic substrate (printed electronic) that is thermally stable.
One of the essential objectives of the present invention is to provide an improved process for manufacturing a functional flexible cellulosic substrate (printed electronic) that is dimensionally stable.
One of the essential objectives of the present invention is to provide an improved process for manufacturing a functional flexible cellulosic substrate (printed electronic) which allows the use of inks that do not require annealing.
One of the essential objectives of the present invention is to provide an improved process for manufacturing a functional flexible cellulosic substrate (printed electronic) which makes it possible to easily and industrially produce multiple layers integrating one or more levels of electrical circuits or circuit boards
One of the essential objectives of the present invention is to provide electronic objects such as circuit boards that are reliable, efficient, economical, and robust, by implementing the process as referred to in one of the above objectives.
One of the essential objectives of the present invention is to provide a simple and economical setup for implementing the process as referred to in one of the above objectives.
One of the essential objectives of the present invention is to provide a kit for implementing the process as referred to in one of the above objectives.

### BRIEF DESCRIPTION OF THE INVENTION

These and other objectives are achieved by the present invention, which firstly relates to a process for manufacturing a flexible cellulosic substrate which comprises at least one functional circuit and/or is akin to at least one functional board, this circuit and/or this board being capable of carrying, circulating, and/or processing a signal, in particular an electrical signal in the case of printed electrical circuits or circuit boards, characterized in that it essentially consists of:
a) preparing or making use of an aqueous fibrous suspension comprising paper pulp and/or pulp of (micro/macro) cellulose fibrils;
b) producing a wet fibrous mat from this suspension;
c) draining this wet fibrous mat;
c′) optionally, pressing this wet fibrous mat;
d) printing one of the faces of the wet fibrous mat by means of at least one functional ink capable of transmitting, emitting, and/or processing at least one signal, in order to produce at least one topography comprising at least one track for circulation of the signal, optionally at least one component capable of acting on the signal;
e) optionally, coating/encapsulating the printed face of the fibrous mat by means of at least one wet, preferably fibrous, layer;
f) optionally at least partially eliminating the water contained in the fibrous mat that is optionally coated in accordance with step e);
g) optionally, coating the printed face of the fibrous mat by means of at least one layer composed of inorganic pigments and of binders;
h) optionally, printing one of the faces of the substrate capable of being obtained as a result of at least one of steps e) to g), by means of at least one functional ink capable of transmitting, emitting, and/or processing at least one signal, in order to produce at least one topography comprising at least one track for circulation of the signal, optionally at least one component capable of acting on the signal.

The process according to the invention is particularly efficient and advantageous in that it consists of printing with functional inks, for example conductive inks (silver or carbon, solvent- or water-based), on a sheet of paper or film of wet cellulose microfibrils during manufacturing, followed by encapsulation of the printed circuit by superimposing a second sheet of paper or film of wet cellulose microfibrils. The two-ply or complex paper is then consolidated by compression and drying under load.

The sequence of printing [step d)]/lamination [step e)] in the wet state can be repeated several times, in order to obtain multilayer structures with 3D circuits integrated within a sheet of paper. The process makes it possible to eliminate lamination processes requiring the use of adhesives (bonding).

In addition, the deposited functional inks cannot drain away in liquid effluents, which constitutes a substantial advantage in ecological terms.

The final product is in the form of a flexible sheet of paper having a thickness of several hundred microns, with a network of functional tracks, for example conductive, embedded within the volume of the paper.

In other aspects, the present invention concerns:
a flexible cellulosic substrate which comprises at least one functional circuit and/or is akin to at least one functional board, single or multilayer, capable of being obtained by the process according to the invention, having a thickness of between 100 and 500 μm, preferably between 200 and 400 μm.
a circuit board manufactured by the process according to the invention, wherein it comprises a grid of sandwich capacitors each formed at the intersection of the electrically conductive tracks P1, P2 framing the grid.
this circuit board is also characterized in that the grid comprises N tracks P1 and N tracks P2, in that the N tracks P1 are capable of each being connected to one of the terminals of an electric generator (input voltage), and in that the N tracks P2 are capable of each being connected to a device for measuring the output voltage so as to evaluate the variation in capacitance of each capacitor in reaction to moisture supplied to said capacitor, this moisture preferably being supplied via the touch of a human finger or by air blown by a human mouth.
this circuit board is also characterized in that it constitutes a keyboard of an electronic device, preferably a computer, a digital tablet, or a smartphone.
a setup for implementing the process according to the invention, wherein it comprises:
   I. optionally at least one device for preparing and refining paper pulp and/or pulp of (micro/macro) cellulose fibrils;
   II. in a discontinuous production mode: at least one system for manufacturing sheets of paper, preferably of the type specified in standard ISO5269 (Rapid-Köthen method), or
      in a continuous production mode: at least one papermaking machine comprising a headbox, a fourdrinier wire—preferably with a flat table, a press section, a dryer, and a reel;
   III. a contactless deposition/printing system, in particular by extrusion, spraying, or inkjetting; and/or a contact deposition/printing system, in particular by screen printing, preferably rotary screen printing, flexography, pad printing, gravure printing, or offset printing;
   IV. at least one functional ink chosen from inks composed of at least one low-polarity solvent slightly miscible in water, preferably from the group comprising—ideally consisting of: colored inks, electrically conductive inks, thermally conductive inks, semiconductive inks, insulating inks, magnetic inks, dielectric inks etc., and mixtures thereof.
A kit for implementing the process according to the invention, wherein it comprises all or part of the setup according to the invention.

### Definitions

Throughout the present description, any singular refers to either the singular or the plural. The definitions given below by way of example may assist with interpreting the present description:
“cellulosic”: comprising cellulose fibers and/or fibrils;
“functional”: describes the pattern/topography printed on the flexible cellulosic substrate; this pattern/this topography, which is able to carry, circulate, and/or process a signal, may be a color, an electrical signal, a thermal signal, an electromagnetic signal, a magnetic signal, a dielectric signal, a semiconductive signal;
“paper pulp”: aqueous suspension of cellulosic fibers or mixture of cellulosic fibers and/or inorganic particles such as talc, kaolin, calcium carbonate, and/or synthetic fibers such as glass fibers, of polymer material and regenerated cellulose (viscose type or more generally obtained by a process of dissolution and spinning of cellulose pulp).
“pulp of cellulose fibrils”: aqueous suspension of macro and/or micro cellulose fibrils.
“wet fibrous mat”: layer of cellulosic fibers whose dryness is at least equal to 3%.
“dryness”: mass fraction of dry matter in the fibrous suspension (determined according to ISO 638: 2008).
“low-polarity solvent”: aprotic solvent or aprotic solvent having a dipole moment of μ≤2 D (debye).
“solvent slightly miscible in water”: solubility of the solvent in water ≤25% w/v [solubility test used: http://full.chemwatch.net/galleria/LEGSREGS/00-0-0-148-0-0-AS-20070417.pdf]
“polar solvent”: protic solvent or aprotic solvent with a dipole moment of μ>2 D (debye).
“solvent miscible in water”: solubility of the solvent in water >25% % w/v [solubility test used:
   http://full.chemwatch.net/galleria/LEGSREGS/00-0-0-148-0-0-AS-20070417.pdf]
“approximately” or “substantially” means to within 10%, or even to within 5%, relative to the unit of measurement used;
“between B1 and B2” means that one and/or the other of the endpoints B1, B2 may or may not be included in the interval [B1, B2].

### DETAILED DESCRIPTION OF THE INVENTION

Process

In a preferred embodiment, the process according to the invention is integrated into a discontinuous manufacturing of paper involving at least one disperser, at least one filtration/draining column equipped with at least one filtration fabric, at least one calibrated cylinder (for example 3 kg) for compression (pressing), and a device for drying the sheet under load.

In another embodiment, the process according to the invention is integrated into an industrial continuous production of paper making use of a papermaking machine comprising at least one headbox, at least one foudrinier wire preferably with a flat table, at least one press section, at least one dryer, and at least one reel.

Step a)

From an aqueous suspension of cellulosic fibers, the fibrous mat can be prepared according to the preparation methods described in the ISO-5269 standard. In particular, this may involve the so-called “German” or “Rapid-Köthen” method.

According to one alternative, this fibrous mat could be obtained by any type of technique using a system of draining by filtration.

According to an advantageous feature of the invention, the suspension used in step a) has a dry matter concentration of between 0.1 and 1% by weight, preferably between 0.2 and 0.5% by weight.

Advantageously, the cellulosic fibers used are characterized by a refining degree of between 20 and 80° SR, preferably between 30 and 70° SR, and more preferably 40 to 60° SR.

This fibrous suspension may for example be a bleached softwood kraft pulp, or alternatively an unbleached softwood kraft pulp, a bleached hardwood kraft pulp, an unbleached hardwood kraft pulp.

Step b)-Steps c) & c′)

In accordance with the preferred discontinuous mode of implementation, the production of the wet fibrous mat according to step b) is carried out in the front filtration column which distributes the suspension from step a) over the width of the filtration fabric.

In accordance with the continuous mode of implementation, the production of the wet fibrous mat according to step b) is carried out by the headbox which distributes the suspension from step a) over the width of the foudrinier wire.

The draining step c), preferably by filtration, of the suspension of cellulosic fibers from step b), takes place on the filtration fabric.

According to an advantageous embodiment of the invention, the dryness of the fibrous mat at the end of the draining (c), preferably by filtration—in % by weight and in increasing order of preference—is between 1 and 60; 1 and 40; 10 and 20; 5 to 20; 10 to 15.

This draining of step (c) is preferably carried out on a fabric or fourdrinier wire of the type used in papermaking.

According to a variant, this draining could be a filtration carried out by means of any type of fabric or fourdrinier wire, membranes, filters having a cut-off threshold between 1 and 200 μm. It is also appropriate, in accordance with the invention, for this wet fibrous mat to have a dry matter area density of between 30 and 100 g/m², preferably between 40 and 80 g/m², and more preferably between 50 and 70 g/m².

Advantageously, the draining c) is carried out in practice by means of vacuum pumps which will suction a certain proportion of the water supplied by the preparation, through the fabric or fourdrinier wire.

This type of forming on fabric or fourdrinier wire causes asymmetry in the sheet thickness. We will distinguish between the two sides of a sheet of paper, respectively called the fabric side and the felt side, the fabric side being the one in contact with the fabric or wire during pulp distribution. This asymmetry can be reduced if the sheet is formed between two fourdrinier wires or lengths of fabric or else by hybrid industrial systems where forming is done on a very short table and then between two fourdrinier wires or lengths of fabric. There is also another type of forming called cylinder forming, where the sheet is formed on a large cylinder which at the same time is suctioning part of the water.

In practice, the pressing c′) can be carried out by means of pressing rollers (calendars).

Step d)

According to a preferred arrangement of the invention, the printing according to step d) is carried out by depositing the functional ink on one of the faces of the fibrous mat, after disappearance of the surface film of water during the draining of step (c), this phenomenon occurring at an overall dryness of the fibrous mat that is greater than 1% by weight and less than or equal to 30% by weight, preferably 15% by weight.

Disappearance of the film of water is indicated not only by the dryness of the fibrous mat being between 1 and 30%, but also by a change in the surface appearance of the fibrous mat. The surface fibers are no longer covered with a film of water and the appearance of the surface of the fibrous mat then becomes dull. This leads in particular to a change in the optical reflection of the surface. This change in the optical surface properties can be analyzed in particular by an objective measurement of the brilliance which is achieved by lighting the surface with a point source and measuring the intensity of the reflected ray at angles set by convention. In this specific case, a drastic drop in brilliance is observed after passing the water line. Preferably, the deposition of functional/printing ink(s) is carried out:
by a contactless deposition/printing process, in particular by an extrusion process, a spray process, or an inkjetting process; or
by a contact deposition/printing process, in particular by a screen printing process, preferably rotary screen printing, a flexography process, a pad printing process, a gravure printing process, or an offset process.

The functional ink is preferably an ink composed of at least one low-polarity solvent slightly miscible with water, this ink being suitably chosen from the group comprising ideally consisting of: colored inks, electrically conductive inks, thermally conductive inks, semiconductive inks, insulating inks, magnetic inks, etc. and mixtures thereof.

The electrically conductive inks are advantageously either inks based on organic polymers (organic inks), inks based on metal particles (inorganic inks), or inks based on carbon.

The organic ink may for example be composed of small molecules or polymers:

| Polymers | | Molecules | |
|---|---|---|---|
| 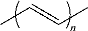 | Polyacetylene | 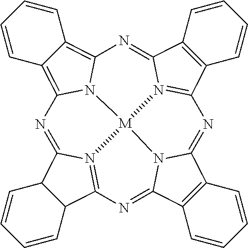 | Phtalocyanine (M = H, metal) |
| 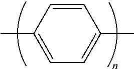 | Polyphenylene | 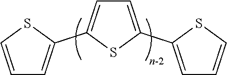 | Oligothiophene (n = 3 to 8) |
| 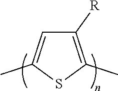 | Polythiophene | 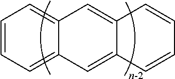 | Polyacene (n = 2 to 5) |
| 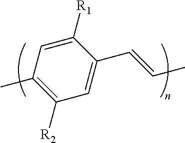 | Polyphenylene vinylene | | |

PEDOT-PSS: blend of two polymers, poly(3,4-ethylenedioxythiophene) (PEDOT) and sodium polystyrene sulfonate (PSS)

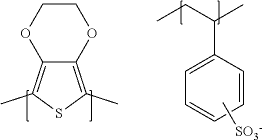

The inorganic inks are for example inks based on particles of conductive metals: silver, gold, nickel, platinum or palladium etc.

The metals are present in the ink in the form of microparticles or nanoparticles that are spherical, tubular, flat etc.

The carbon-based inks are for example inks based on carbon nanotubes, optionally doped with carbon black.

All these functional inks are preferably composed of at least one low-polarity solvent slightly miscible in water.

These are advantageously inks in which the solvent is non-aqueous, for example organic.

For example, they may be glycol ethers-esters (in particular acetates) such as 1-methoxy-2-propyl acetate. This solvent prevents the ink from spreading on the wet fibrous mat after printing, a consequence of physicochemical affinities.

All these inks advantageously contain a cosolvent miscible in water, for example a compound from the family of glycol ethers such as (2-Butoxyethoxy) ethanol, in order to:
Adapt the viscosity of the ink to the printing process. In particular, to thin the ink for processes such as spraying, inkjetting, or flexography.
Facilitate the concentration and isolation of the functional material on the surface of the fibrous mat, by selective migration of the cosolvent into the substrate after printing.

All these inks are characterized by significant viscosity after printing, for example greater than or equal to 10, 15, or even 20 Pa·s, minimizing ink penetration by capillary effect into the fibrous mat during the pressing step.

Advantageously, the viscosity of these inks is adapted to the printing process used. Thus, these can be Newtonian inks having a viscosity between 5 and 100 mPa·s or shear thinning inks having a viscosity at 1 s(−1) between 20 and 500 Pa·s and a viscosity at 1000 s(−1) between 0.5 and 10 Pa·s.

The viscosity and theological behavior are measured with a cone-plane or plane-plane rheometer (depending on the type of inks characterized) such as the Anton Paar MCR-302 rheometer.

Optional Step e)

This step e), which takes place when one wishes to produce a flexible “sandwich” substrate structure, consists of superimposing at least one wet layer on the printed face of the fibrous mat.

This wet layer is advantageously:
composed of a mat of cellulosic fibers;
obtained by draining via filtration, spraying, or more generally by contactless coating techniques.

According to a discontinuous mode of implementing the process according to the invention, the application of this fibrous layer can be carried out by superposition of at least one wet fibrous mat, preferably created in accordance with the preparation methods described in standard ISO-5269. In particular, it may involve the so-called “German” or “Rapid-Köthen” method.

According to a continuous mode of implementing the process according to the invention, the application of this fibrous layer can be carried out on multilayer papermaking machines comprising several forming systems (headbox and fourdrinier filtration fabric) in parallel.

Step f)

After the printing step d) and/or the possible coating/encapsulation step e), this step f) of water elimination takes place, preferably broken down as follows:
f.1. pressing the wet fibrous mat to bring its dryness between 5 and 40% by weight, preferably between 8 and 35% by weight;
f.2. drying the pressed fibrous mat to bring its dryness to a value greater than or equal to, in % by weight and in increasing order of preference: 35; 45; 60; 80; 95; 98; this drying preferably being carried out at a temperature between 50 and 180° C., preferably between 60 and 150° C.;
f.3. optionally a post-processing heat treatment, preferably at a temperature greater than or equal to 180° C., more preferably between 190 and 250° C.
f.1. The pressing is preferably carried out in accordance with what can occur in the press section of a papermaking machine, using pressure to eliminate the water contained in the wet fibrous mat, printed or not, coated with at least one wet fibrous layer, printed or not. The purpose of this operation is to give the sheet a certain resistance and to reduce the water as much as possible before reaching the dryer. The press may be of different types, either simply covered with an absorbent material, felt, or additionally perforated to be able to suction out part of the water, or even be grooved or have an intermediate plastic fabric.
f.2. The drying may advantageously be of the type found in the drying portion of a papermaking machine.
This removes the rest of the water by evaporation, using heat and air. Several techniques are usable, some with contact (conduction drying) and others without contact (convection, radiation). In the first case, the dryers are for example huge cylinders of cast iron heated internally by steam. Other techniques use convection methods, meaning the circulation of hot air directed towards the sheet. There are also dryers using IR, electric, or gas radiation.
This step is controlled so that the flexible printed substrate is given desirable mechanical properties: rigidity, tensile strength, tear or burst strength, or dimensional stability.
f.3. The post-processing heat treatment may for example be calendaring at high temperature and low pressure.

Step g)

This step consists of coating the printed face of the fibrous mat with at least one layer composed of inorganic pigments and of binders.

In the preferred discontinuous mode of implementing the process according to the invention, this step is carried out by means of a spray nozzle, or more generally by contactless coating techniques such as curtain coating, air knife coating, etc.

Advantageously, the inorganic pigments are chosen from the group comprising: talc, calcium and/or magnesium carbonate, kaolin, and more generally any type of pigments belonging to the family of metal oxides, sulfates, and silicates. As for the binders, they are preferably selected from synthetic latexes (such as styrene butadiene or polyvinyl alcohol), binders of natural origin such as starches, celluloses such as carboxymethylcellulose, polylactic acid, proteins of animal or plant origin (e.g. casein, soy, etc.).

Optional Step h)

This optional step (h) can supplement the printing step (d).

It therefore involves printing one of the faces of the substrate resulting from at least one of steps e), f), g), by means of at least one functional ink capable of transmitting, emitting, and/or processing at least one signal, in order to produce at least one topography comprising at least one track for circulation of the signal, optionally at least one component capable of acting on the signal.

The features of step (d) described above apply mutatis mutandis to this step (h).

To manufacture functional flexible paper substrates—for example electronics—having a “sandwich” or “multilayer” structure, it is possible according to one variant of the invention to repeat the sequence comprising the steps of printing (d), coating/encapsulation (e), and/or coating with inorganic pigments and with binders (g), or even water elimination (f) and/or additional printing (h).

Optional Step i)

This involves a step of eliminating at least one section of the coating/encapsulation layer(s), in order to expose at least a portion of the printing.

This “stripping” step is implemented in the case where a coating/encapsulation of the printed face of the basic wet fibrous mat obtained in step c), or of the face printed with a coating/encapsulation layer of step (e), has been carried out.

According to one noteworthy feature of the invention, the process for manufacturing functional flexible paper substrates, for example electronics, may be an in-line continuous industrial process.

In this case, the functional flexible substrates obtained may also be packaged on reels, similarly to what occurs in paper manufacturing.

These reels may be parent reels which can then be unwound and slit into roll sets having the characteristics requested by the end user (length, diameter, regular tension, dust-free cut, mandrel to specifications, traceability, visible splices).

The roll sets are capable of being transformed into sheets or a format with a determined and precise width and length, corresponding to the specifications of the desired functional printed circuits/functional boards, for example circuit boards. In one particular embodiment of the process according to the invention, the manufactured object is a circuit board comprising at least one printed circuit and at least one electronic component, the latter preferably being an interdigital capacitor or a sandwich capacitor.

Advantageously, in this particular embodiment:
N parallel electrically conductive tracks P1 are printed on a wet fibrous mat during step d),
then step e) of coating/encapsulating the printed tracks with a wet fibrous layer is implemented,
step d) is reproduced by printing N parallel electrically conductive tracks P2 on the free face of the wet fibrous layer, perpendicular to tracks P1,
the water is eliminated according to step f),
and, optionally, the entire sequence of steps is repeated [step e)/step d)], step f) at the end of at least a portion of the sequences and/or at the end of the last sequence.

Objects Resulting or Capable of Resulting from the Process

These objects are flexible cellulosic substrates which comprise at least one functional circuit and/or are akin to at least one functional board, single or multilayer, having a thickness between 50 and 500 μm, preferably between 200 and 400 μm.

The average grams per square meter of these flexible substrates is for example between 10 and 200 g/m², preferably 30 and 100 g/m², and, more preferably between 50 and 70 g/m². According to one noteworthy feature of the invention, the relative permittivity of these flexible substrates is for example between 1 and 10, preferably 2 and 8, and more preferably 3 and 5.

This relative permittivity is measured according to the ASTM D150-11 standard, Standard Test Methods for AC Loss Characteristics and Permittivity (Dielectric Constant) of Solid Electrical Insulation.

The process according to the invention, which is a process for printing or even encapsulating functional inks on a flexible, single or multilayer paper substrate, opens doors in many technical fields and in particular that of printed electronics. The electrically conductive functional inks of the substrates obtained by the process form an integral part of said substrates.

The printed patterns or topographies may comprise not only conductive tracks (printed circuits), but also electronic components such as resistors, capacitors, diodes, transistors, LEDs, chips, microcontroller sensors, and other processors.

These electronic components may be exogenous and subsequently integrated into the circuit boards formed by the flexible substrates according to the invention, but it is also possible, by printing topographies and patterns using conductive inks within the substrate, to use the electrical characteristics of paper to produce endogenous electronic components.

The functional flexible substrates thus obtained become completed electronic devices capable of interacting with end users.

Thus, another of the objects resulting from the process can be a circuit board manufactured by the process of the invention, composed of a grid of sandwich capacitors each formed at the intersection of the tracks P1 and P2.

In one particular embodiment, this circuit board is characterized in that the N tracks P1 are capable of each being connected to one of the terminals of an electric generator (input voltage), and in that the N tracks P2 are capable of each being connected to a device for measuring the output voltage so as to evaluate the variation in capacitance of each capacitor in reaction to moisture supplied to said capacitor, this moisture preferably being supplied via the touch of a human finger or by air blown by a human mouth.

This circuit board is therefore usable for touch-detection applications. More specifically, the application aims to use the dielectric characteristics of the paper substrate to create moisture variation sensors, in order to activate areas of the paper substrate. The aim is then to obtain a keyboard reactive to the breath or touch of the user.

Such a circuit board can therefore constitute, in accordance with the invention, a keyboard of an electronic device, preferably a computer, a digital tablet, or a smartphone.

In addition to these electronic devices on flexible printed paper substrates, the objects resulting or capable of resulting from the process according to the invention can also be intelligent packaging, safety packaging, medical packaging, etc., in which RFID antennas, magnetic strips, or humidity sensors can be encapsulated.

In the case where the functional inks deposited in the base of the substrate paper according to the invention are tracers (colored, magnetic, resistive) which remain hidden in the structure of the paper substrate, this opens the way for papers with specific signatures for “security paper” applications.

Other potential applications and advantages of the invention of this technique include the following:
A1. Creation of a two-ply sheet with strong cohesion, which would hide the pattern initially printed on the first sheet without the need for a lamination step which complicates recycling.
A2. For the application described in A1 above as well as for others, high conductivity is not necessary. The invention therefore makes it possible to develop economical aqueous inks which can be sprayed.
A3. Optimization of the fiber composition, the refining, and the various additives allow achieving a level of performance in terms of conductivity, definition of the printed patterns, and penetration into the fibrous layer, this latter point potentially enabling good performance in terms of flexural strength.
A4. Functional flexible substrate for measuring load distribution, in particular via: (i) the printing and encapsulation of flat capacitors for the manufacture of sensing floor coverings, (ii) the printing and encapsulation in packaging boxes of interdigital capacitors which can be used as strain gauges.
A5. Conductive functional flexible substrate obtained by depositing a structured pattern or a continuous layer (flat) on the wet fibrous mat, capable of being used in the potential manufacture of anti-static means or electromagnetic screens.

Setup

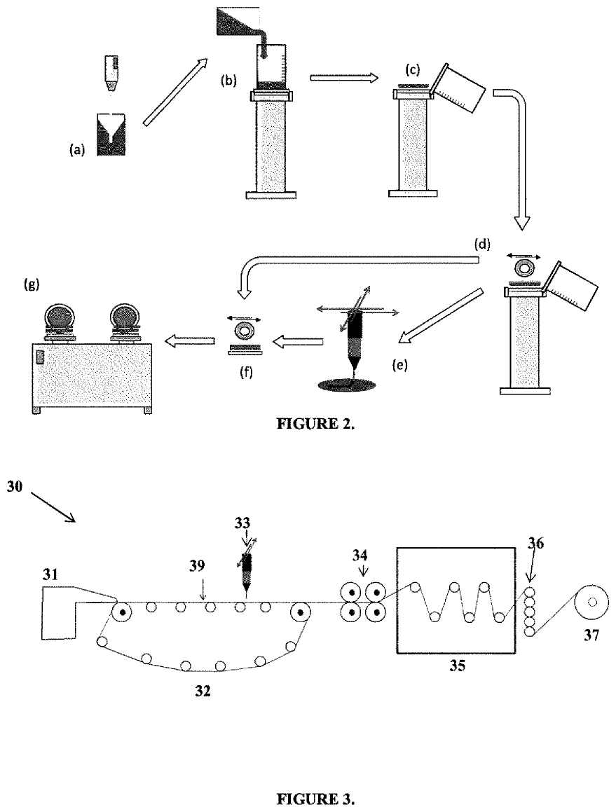

In another of these aspects, the present invention relates to two setups for implementing the described process.
A setup allowing the discontinuous production of individual sheets and suitable for low production rates, comprising (FIG. 2):
   I. optionally at least one device for preparing and refining paper pulp and/or pulp of cellulose fibrils;
   II. at least one machine according to the methods for preparing sheets of paper described in standard ISO-5269. In particular, this may involve the so-called “German” or “Rapid-Köthen” method.
   III. a contactless deposition/printing system, in particular by extrusion, spraying, or inkjetting; and/or a contact deposition/printing system, in particular by screen printing, preferably rotary screen printing, flexography, pad printing, gravure printing, or offset printing;
   IV. at least one functional ink composed of at least one low-polarity solvent slightly miscible in water, this ink preferably being chosen from the group comprising—ideally consisting of: colored inks, electrically conductive inks, thermally conductive inks, semiconductive inks, insulating inks, magnetic inks, etc., and mixtures thereof.
A setup on a continuous papermaking machine allowing the continuous production of sheets, comprising (FIG. 3):
   I. optionally at least one device for preparing and refining paper pulp and/or pulp of cellulose fibrils;
   II. at least one papermaking machine comprising a headbox, a fourdrinier wire—preferably with a flat table, a press section, a dryer, and a reel;
   III. a contactless deposition/printing system, in particular by extrusion, spraying, or inkjetting; and/or a contact deposition/printing system, in particular by screen printing, preferably rotary screen printing, flexography, pad printing, gravure printing, or offset printing;
   IV. at least one functional ink composed of at least one low-polarity solvent slightly miscible in water, this ink preferably being chosen from the group comprising—ideally consisting of: colored inks, electrically conductive inks, thermally conductive inks, semiconductive inks, insulating inks, magnetic inks, etc., and mixtures thereof.

The attached FIGS. 2 and 3 show one embodiment of these setups.

FIG. 2 shows the manufacturing of circuits encapsulated according to a discontinuous laboratory process using a Rapid-Köthen fibrous mat manufacturing protocol. (a) Suspending the cellulosic fibers in a laboratory disperser (Lhomargy or similar). (b) Introducing the suspension into the Rapid-Köthen filtration bowl. (c1) forming the fibrous mat and draining the wet fibrous mat. (c2) Pressing the wet fibrous mat. (d) Depositing the conductive ink by extrusion. (e) Superimposing a second wet fibrous mat on the printed fibrous mat. (f) Drying the double layer paper under load and annealing the ink. FIG. 3 illustrates a papermaking machine 30 with flat table, comprising a head box 31, a fourdrinier wire 32, a printing system 33 (for example by extrusion, inkjetting, screen printing, preferably rotary screen printing, flexography, etc.), a press section 34, a dryer 35, a calendar 36, and a reel 37.

The fibrous mat 38 travels on the fourdrinier wire 32. This wire enables the elimination of the film of water starting from the water line 39, out of the wire 32.

Kit

The present invention also relates to a kit for implementing the process. This kit is characterized in that it comprises all or part of the setup according to the invention and all or part of the inks and/or components used in the manufacturing according to the invention.

This kit, which forms a packaged unit for sale, may also comprise an instruction leaflet on implementing the process using the setup and the inks and/or components contained in the kit.

### EXAMPLES

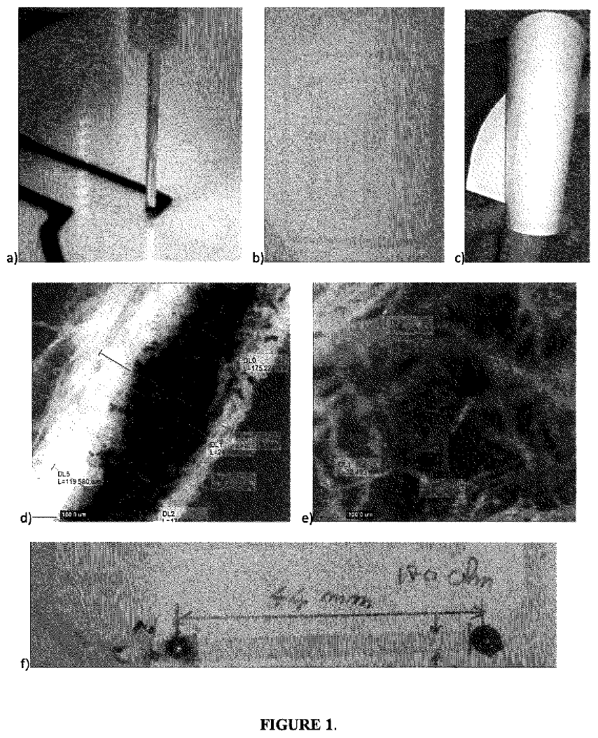

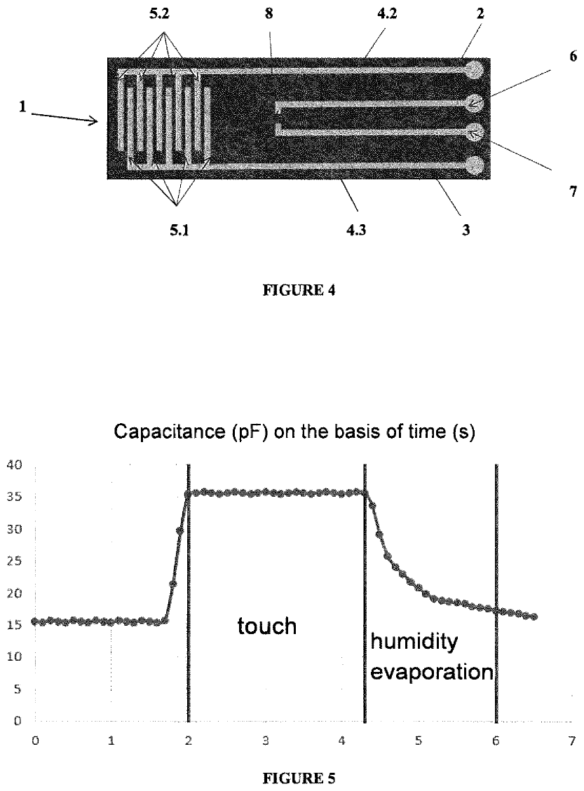

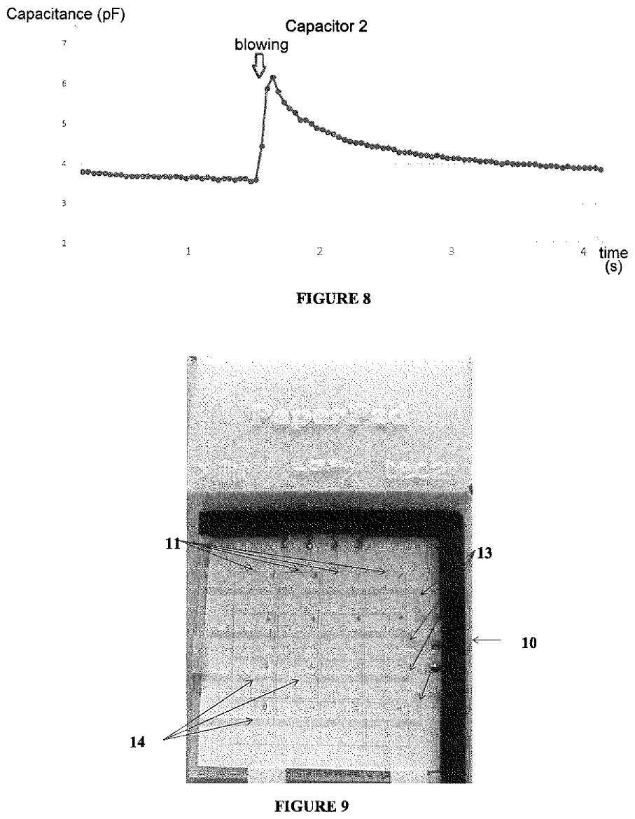

The following examples illustrate the use of the process according to the invention in order to create four flexible cellulosic substrates printed with a functional ink:
Example 1: circuit printed with a carbon-based ink using a 3D printer and encapsulated: attached FIGS. 1a; 1b; 1c; 1d; 1e; & 1f.
Example 2: circuit board comprising a circuit printed with a carbon-based ink by means of a screw pump with deposition nozzle, so as to form a flat interdigital capacitor and two tracks supplying power to an LED and to the encapsulated exogenous LED: attached FIGS. 4, 5 & 6;
Example 3: circuit board comprising a circuit printed with a carbon-based ink by means of a 3D printer, so as to form a matrix of encapsulated flat capacitors: grid of 4×4 power supply tracks: attached FIGS. 7, 8 & 9;

The description of these examples is made with reference to the attached figures in which:

FIG. 1a is a photograph showing the deposition of conductive carbon-based ink, using a modified Prusa i3 3D printer, on a wet fibrous mat in accordance with step b) of the process implemented in Example 1;

FIG. 1b is a photograph of part of the printed circuit encapsulated in wet paper after pressing and drying, respectively in accordance with steps (f.1) and (f.2) of the process implemented in Example 1;

FIG. 1c is a photograph of the printed circuit encapsulated in wet paper after rolling, produced in accordance with the process used in Example 1;

FIG. 1d is a photograph under an optical microscope at magnification 400 of a transverse section along section line D-D of FIG. 1b;

FIG. 1e is a photograph under an optical microscope at magnification 400 of a top view of the paper of FIG. 1b, encapsulating a printed circuit, showing the stripping by abrasion [step (i)] of a portion of the encapsulation layer in order to uncover an electrical contact;

FIG. 1f is a photograph of a printed and encapsulated circuit in accordance with the process according to the invention implemented in Example 1, in which the printed circuit is a straight electrically conductive track 3 mm wide, 44 mm long, and 0.209 mm thick;

FIG. 2 is a diagram showing an example setup for the preferred discontinuous mode of implementing the process according to the invention;

FIG. 3 is a diagram showing an example setup for a continuous mode of implementing the process according to the invention;

FIG. 4 is a diagram of an element of the circuit board comprising: a printed flat sensor formed by an interdigital capacitor and conductive tracks supplying power to an LED, and an LED component installed in this printed circuit, in accordance with Example 3;

FIG. 5 is a curve showing the capacitance (pF) of the interdigital capacitor of FIG. 4 as a function of time, before and after contact between a human finger and the portion of the paper encapsulation layer located immediately above the capacitor;

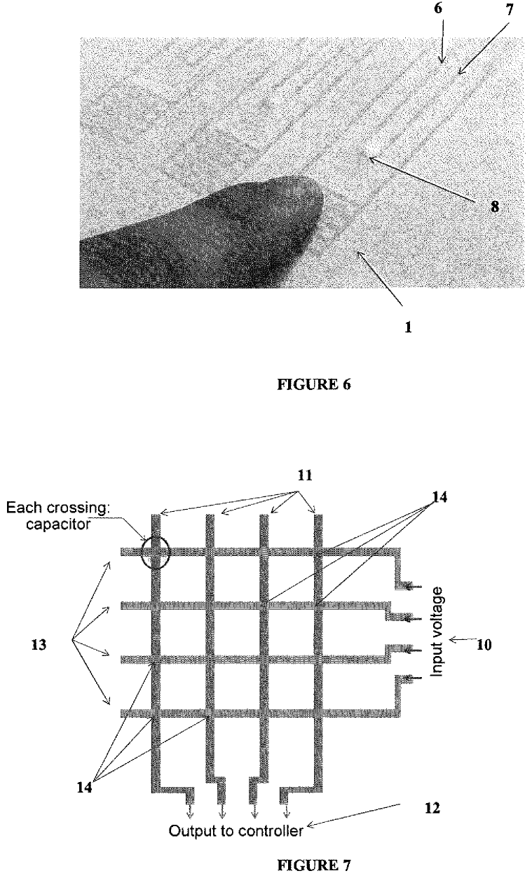

FIG. 6 is a photograph showing the touch of a human finger above the capacitor mentioned in the description of FIG. 5, said capacitor being part of a circuit board comprising several elements identical to the one referred to in FIG. 4;

FIG. 6 is a diagram of an element of the circuit board comprising a matrix of flat capacitors formed at the intersection of 4×4 conductive parallel tracks printed and encapsulated in accordance with Example 4 to form a touch keyboard;

FIG. 8 is a curve showing the capacitance (pF) of a flat capacitor of the matrix of FIG. 7 as a function of time, before and after a brief breath emitted by a person on the portion of the paper encapsulation layer located just above said capacitor;

FIG. 9 is a general photograph from above of the circuit board forming a touch keypad, manufactured in accordance with Example 4 of implementing the process according to the invention.

### EXAMPLE 1

### Manufacture of a Flexible Cellulosic Substrate Composed of a Circuit Formed by One or More Printed Conductive Tracks, on a Wet Fibrous Mat, Said Tracks Encapsulated by a Superimposed Wet Fibrous Layer, the Whole being Dried Under Load to Consolidate the Cohesion of the Double Layer. (FIG. 1b)

Discontinuous setup presented in FIG. 2 and supplemented by the system for preparing the aqueous cellulosic suspension and by a printing system.

Raw materials: cellulosic pulp (bleached hardwood fibers refined to 50° SR) and commercial conductive ink based on carbon in non-aqueous solvent.

Methodology: In the embodiment used for this example, the following operations were carried out:
a) Suspension of cellulosic fibers created in a standard device (Lhomargy type) (according to standard ISO-5263-1: 2004)
b) & c) Consolidated fibrous mat created using a machine in accordance with the preparation methods described in standard ISO-5269. This is the so-called “German” or “Rapid Köthen” method which, at the end of the draining phase, makes it possible to obtain a dryness of around 10-15% and a dry matter content of approx. 60 g/m²,
c′) Optionally the fibrous mat is pressed using a flexible roller of 3 kg (corresponding to a linear pressure of 15 kg/m).
d) The wet sheet is then printed according to the following step (d).

The wet fibrous mat of step (c′) is printed with conductive tracks using a volumetric dosing system (such as a syringe pump or a Moineau positive displacement micropump).
e) Superimposition of a wet sheet previously prepared according to step (b).
f) The double layer is dried by following the end of the ISO-5269 procedure.
i) The contacts are exposed by localized abrasion of the surface cellulosic layer. In the case of this example, a conical grinding wheel on a silicon carbide rod (i.e. 4.8 mm Dremel wheel) was used.

Method and instruments used for characterization by microscopy of the obtained product. The developed sample is analyzed by optical microscopy (Dino-Lite type of instrument); the electrical resistance of the conductive track or tracks is measured using a Fluke 116 type of multimeter.

FIG. 1:

a) Deposition of commercial conductive ink based on carbon in non-aqueous solvent, with modified Prusa i3 3D printer, b) printed circuit encapsulated in wet paper after drying, c) rolled encapsulated circuit, d) lateral section of an encapsulated track, e) image of the track exposed by abrasion of the paper layer, f) conductivity measurement of a track (track width 3 mm, average thickness 0.209 mm, length 44 mm, resistance 170 Ohm, conductivity ˜410 S/m.

### EXAMPLE 2: CIRCUIT BOARD COMPRISING PRINTED FLAT INTERDIGITAL CAPACITORS USEFUL AS TOUCH SENSORS

### 2.1 Without LED Controller

Paper, and more precisely cellulose, is a dielectric, i.e. an insulator, that is not electrically inert: that has, on the atomic scale, electrostatic dipoles which interact with external electromagnetic fields. The quantity that characterizes the dielectrics is dielectric permittivity, which describes the polarization of the material.

This example illustrates the use, in accordance with the invention, of paper as a dielectric in printed flat interdigital capacitors. More specifically, the porosity and the variation in wetness of the paper have the effect of varying the capacitance of these capacitors.

Thus, in this example, circular sheets of paper of 314 cm² (called hand sheets) are manufactured which integrate touch sensors (switches) each associated with an LED indicator, using the printing/encapsulation process that is the object of the present invention.

### Step a)

1 liter of fibrous suspension of 2 g/l bleached kraft cellulose fibers (resinous) refined to 57° SR is used.

Step b)-Step c)

A circular wet fibrous mat of 314 cm² (20 cm in diameter) was manufactured by filtration/draining (Rapid-Köthen method), to obtain a dryness of approximately 10-15% and a dry matter content of approx. 60 g/m².

Step c′)

The fibrous mat is then pressed using a 3 kg flexible roller (corresponding to a linear pressure of 15 kg/m).

### Step d)

A commercial conductive ink based on carbon in non-aqueous solvent is deposited using a system of direct dosing by screw pump with a deposition nozzle having an internal diameter of 400 μm (nozzle-fibrous mat distance approximately 300 to 500 μm, deposition rate approximately 200 mm/min) As shown in FIG. 4, each printed capacitor 1 comprises a positive comb 2 and a negative comb 3. Each comb is formed by a stem 4.2 & 4.3 having perpendicular teeth 5.1 & 5.2 extending from its end in an interdigital manner, meaning nested between one another. The circuit comprises parallel printed connectors 6 and 7, connected to an LED 8.

The tracks 4.2, 4.3, 5.1, 5.2 forming the interdigital capacitor 1 and the connectors 6, 7 of the LED have a width of 1 mm and a thickness of 400 μm (before drying).

C=ε×S/d(1), Using equation (1)

where C is the capacitance of the capacitor, c the relative permittivity of the separator (paper), S the electrode cross-sectional area, and d the distance between the electrodes;

the capacitor 1 is sized to reach a capacitance of approx. 1 pF, which dictates a spacing of 500 μm between the teeth 5.1 & 5.2 of the capacitor 1 and a cumulative length of the interdigital electrodes of 9 cm (FIG. 4).

### Step e)

After the tracks have been deposited, the LED is positioned and a layer of wet fibrous mat (prepared according to steps a, b, c and c′) is superimposed in order to encapsulate the printed circuits.

### Step (f.1)

The mat/circuit/encapsulation layer assembly is pressed using a 3 kg flexible roller (corresponding to a linear pressure of 15 kg/m).

### Step (f.2)

The pressed mat/circuit/encapsulation layer assembly is dried under load (approximately 0.5 to 2 bars) at 95° C. for 20 min (Rapid Köthen method, Franck type dryer, TAPPI T 205 standard practice).

Several flexible cellulosic substrate sheets are obtained, each comprising several capacitor 1/LED 8 assemblies.

### Characterization

The interdigital capacitor thus produced shows a variation of more than 75% of the value of its initial capacitance (i.e. from 15 to 35 pF, FIG. 4), at the approach of a human finger (relative permittivity of approximately 60). This variation in the capacitance value makes it possible to very clearly detect the approach to and touching of the sensor by a human finger.

The application of a voltage of 5 V across the terminals of the connectors 6, 7 connected to the encapsulated LED 8 makes it possible to light the diode, which proves that the encapsulation process guarantees good electrical contact and makes it possible to keep the LED 8 in place without the need to use conductive adhesives or solder paste.

FIG. 5 shows that after touching the sensor, some time (approximately two seconds) is necessary for the evaporation/dispersion of the humidity in the fibrous structure of the paper in order to return to the initial state of the capacitor.

2.2 with LED Controller

Example 2.1 is reproduced while integrating, into each interdigital capacitor 1/LED 8 assembly, an external controller (Arduino MEGA 2560) allowing the supply of power to the LED 8 when the capacitance of the capacitor varies significantly (a detection threshold is fixed at around 25 pF, so that the small variations generated by external interference are not detected). The use of the LED 8 provides a simple way to illustrate that the sensor has been activated (see FIG. 6). It is important to note that this circuit is completely integrated into the paper.

### EXAMPLE 3: CIRCUIT BOARD COMPRISING PRINTED FLAT SANDWICH CAPACITORS USEFUL AS BREATH SENSORS—BREATH-SENSITIVE KEYBOARD OBTAINED USING THIS BOARD

### 3.1 Printed Flat Sandwich Capacitors Useful as Breath Sensors

This example concerns the manufacturing of a circuit board according to the invention, the board comprising breath-sensitive sensors, where the goal is to create keyboard keys which are therefore activated by localized blowing through a straw. This application most particularly concerns quadriplegic users.

The printed capacitors in this example are sandwich sensors in a matrix. The circuit board 10 shown in FIGS. 7 and 9 comprises a printed circuit formed by four parallel conductive tracks 11, each connected by one of their ends to an Arduino MEGA 2650 controller 12 which allows detecting variations in capacitance, and by four parallel conductive tracks 13, perpendicular to tracks 11 and capable of each being connected by one of their ends to one of the poles of a generator not shown in FIG. 7 and FIG. 8.

### Methodology:

### Step a)

1 liter of fibrous suspension of 2 g/I bleached kraft cellulose fibers (resinous) refined to 57° SR is used.

Step b)-Step c)

A circular wet fibrous mat of 314 cm² (20 cm in diameter) was manufactured by filtration (Rapid-Köthen method), to obtain a dryness of approximately 10-15% and a dry matter content of approx. 60 g/m².

Step c′

The fibrous mat is then pressed using a 3 kg flexible roller (corresponding to a linear pressure of 15 kg/m).

### Step d

The parallel tracks 11 are printed on the wet fibrous mat using a solvent-based (non-aqueous) carbon-based conductive ink and a system of direct dosing by screw pump with a deposition nozzle having an internal diameter of 400 μm (nozzle-fibrous mat distance approximately 300 to 500 μm, deposition rate approximately 200 mm/min).

The printing conditions are summarized in the following table:

Dimensions

| | | |
|---|---|---|
| Number of capacitors | 16 | |
| Width of electrodes | 4 | mm |
| Thickness of deposited ink (not dried) | 500 | μm |

Printing Parameters

| | | |
|---|---|---|
| Ink | Carbon-based solvent | |
| Paper substrate | Resinous fiber | |
| Refining | 57 | ° SR |
| Number of layers | 2 | |
| Printing speed | 300 | mm/min |

The printed tracks are covered with a superimposed fibrous encapsulation layer (prepared according to steps a, b, and c′), parallel tracks 13 then being printed on the free face thereof.

### Step e

A superimposed fibrous encapsulation layer, prepared according to steps a, b, c and c′, is then placed and compacted on parallel tracks 13.

Tracks 11 and 13 have a width of 4 mm and a length of 100 mm.

The areas located at the intersections of the tracks 11 and 13 form sixteen capacitors 14. This matrix topography makes it possible to increase the density of the sensors while reducing the number of necessary connections to the controller 12 (i.e. for a grid of 16 capacitors, only four rows and four columns, or eight connections, to the controller are required).

Interdigital sensors require two connections per capacitor: 32 for a grid of 16 capacitors 14.

### Step f

The multilayer structure was compacted by applying a linear pressure of 15 kg/m and dried under compression at 95° C. (Rapid-Köthen method).

### Characterization

The Arduino MEGA 2560 controller measures the variations in capacitance in the capacitor and transfers the data to a spreadsheet enabling their display in FIG. 8. This figure shows a sudden increase in capacitance (from 3.8 to 6.2 pF) corresponding to the moment when the user blows through a straw on the key of the keyboard. As in Example 3.1, it takes approximately four seconds to return to the value of the initial capacitance. The use of sandwich capacitors is therefore very advantageous in that it allows breath detection. A sensitive keyboard has therefore been produced. As shown in Example 2.1 with flat interdigital capacitors, sandwich capacitors are also subject to a variation in their capacitance when a finger approaches, which allows them to be used for the production of sheets that are touch- and breath-sensitive.

### 3.2 Breath- (or Contact-) Sensitive Keyboard

The breath-sensitive keyboard 10 shown in FIG. 9 is almost identical to the circuit board 10 comprising the grid of sandwich capacitors integrated into the paper (encapsulation) of Example 3.1. Numeric keys (keypads), such as the ones located on the right side of standard computer keyboards, have been marked on the upper face of the circuit board. The sixteen keys thus correspond to the sixteen capacitors 14.

Four tracks 13 (horizontal electrodes) are successively supplied power and the output voltage of four tracks 11 (vertical electrodes) is measured to evaluate the variation in capacitance of each capacitor 14, and thus to detect the variations in humidity of the paper, generated by the user's breath (or the presence of a finger in contact with the paper). The capacitance variations in the sixteen capacitors 14 are detected by the controller 12 which is not shown in FIG. 9 but is present in FIG. 8 showing the board of Example 4. A threshold, making it possible to define a limit to the rate of variation in capacitance beyond which an event is detected, is implemented and integrated in a controller 12 which, by communicating with a computer via a USB connection, will write the symbol corresponding to the key activated by the breath, as a standard keyboard would do.

1. Process for manufacturing a flexible cellulosic substrate which comprises at least one functional circuit and/or is akin to at least one functional board, this circuit and/or this board being capable of carrying, circulating, and/or processing a signal, in particular an electrical signal in the case of printed electrical circuits or circuit boards, characterized in that it essentially consists of:
a) preparing or making use of an aqueous fibrous suspension comprising paper pulp and/or pulp of cellulose fibrils;
b) producing a wet fibrous mat from this suspension;
c) draining this wet fibrous mat;
c′) optionally, pressing this wet fibrous mat;
d) printing one of the faces of the wet fibrous mat using at least one functional ink capable of transmitting, emitting, and/or processing at least one signal, in order to produce at least one topography comprising at least one track for circulation of the signal, optionally at least one component capable of acting on the signal;
e) optionally, coating the printed face of the fibrous mat by means of at least one wet, preferably fibrous, layer;
f) optionally at least partially eliminating the water contained in the fibrous mat optionally coated in accordance with step e);
g) optionally, coating the printed face of the fibrous mat by means of at least one layer composed of inorganic pigments and of binders;
h) optionally, printing one of the faces of the substrate capable of being obtained as a result of at least one of steps e) to g), by means of at least one functional ink capable of transmitting, emitting, and/or processing at least one signal, in order to produce at least one topography comprising at least one track for circulation of the signal, optionally at least one component capable of acting on the signal.

2. Process according to claim 1, wherein the suspension used in step a) has a dry matter concentration of between 0.1 and 1% by weight.

3. Process according to claim 1, wherein the printing according to step d) is carried out by depositing the functional ink on one of the faces of the fibrous mat, after disappearance of the surface film of water during the draining of step (c), this phenomenon occurring at an overall dryness of the fibrous mat that is greater than 1% by weight and less than or equal to 30% by weight, preferably 15% by weight.

4. Process according to claim 1, wherein it is integrated into a discontinuous manufacturing of paper involving at least one disperser, at least one filtration/draining column equipped with at least one filtration fabric, at least one calibrated cylinder for compression, and a device for drying the sheet under load.

5. Process according to claim 1, wherein the functional ink is chosen from inks composed of at least one low-polarity solvent slightly miscible in water, preferably from the group comprising—ideally consisting of: colored inks, electrically conductive inks, thermally conductive inks, semiconductive inks, insulating inks, magnetic inks, dielectric inks, and mixtures thereof.

6. Process according to claim 1, wherein it is integrated into an industrial continuous manufacturing of paper making use of a papermaking machine comprising a headbox, a fourdrinier wire—preferably with a flat table, a press section, a dryer, and a reel.

7. Process according to claim 1, wherein the manufactured object is a circuit board comprising at least one printed circuit and at least one electronic component, the latter preferably being an interdigital capacitor or a sandwich capacitor.

8. Flexible cellulosic substrate capable of being obtained by the process according to claim 1, and which comprises at least one functional circuit and/or is akin to at least one functional board, single or multilayer, wherein it has a thickness between 100 and 500 μm, preferably between 200 and 400 μm.

9. Circuit board manufactured by the process according to claim 6, wherein it is composed of a grid of sandwich capacitors each formed at the intersection of electrically conductive tracks P1, P2 forming the grid.

10. Circuit board according to claim 8, wherein it constitutes a keyboard of an electronic device, preferably a computer, a digital tablet, or a smartphone.

11. Setup for implementing the process according to claim 1, comprising:
I. optionally at least one device for preparing and refining paper pulp and/or pulp of (micro/macro) cellulose fibrils;
in a discontinuous production mode: at least one system for manufacturing sheets of paper preferably of the type specified in standard ISO 5269 (Rapid-Köthen method); or in a continuous production mode: at least one papermaking machine comprising a headbox, a fourdrinier wire—preferably with a flat table, a press section, a dryer, and a reel;
II. a contactless deposition/printing system, in particular by extrusion, spraying, or inkjetting; and/or a contact deposition/printing system, in particular by screen printing, preferably rotary screen printing, flexography, pad printing, gravure printing, or offset printing;
at least one functional ink chosen from inks composed of at least one low-polarity solvent slightly miscible in water, preferably from the group comprising—ideally consisting of: colored inks, electrically conductive inks, thermally conductive inks, semiconductive inks, insulating inks, magnetic inks, dielectric inks, and mixtures thereof.
